(19) United States
(12) Patent Application Publication
(10) Pub. No.: US 2025/0040366 A1
(43) Pub. Date: Jan. 30, 2025

(54) TRANSPARENT DISPLAY DEVICE

(71) Applicant: LG Display Co., Ltd., Seoul (KR)

(72) Inventor: SungSik SON, Paju-si (KR)

(73) Assignee: LG Display Co., Ltd., Seoul (KR)

(21) Appl. No.: 18/759,306

(22) Filed: Jun. 28, 2024

(30) Foreign Application Priority Data
Jul. 24, 2023 (KR) 10-2023-0095716

(51) Int. Cl. H10K 59/127; H10K 59/80

(52) U.S. Cl. CPC H10K 59/1275; H10K 59/872; H10K 59/879; H10K 59/8792

(57) ABSTRACT

A transparent display device can include a transparent display panel including a display area and a non-display area disposed outside of the display area, a first substrate and a second substrate bonded together, the first substrate and the second substrate including the display area, and the display area including a transmissive area and an emission area, an anti-ultraviolet member including a first anti-ultraviolet layer disposed on a lower portion of the transparent display panel, a second anti-ultraviolet layer disposed on an upper portion of the transparent display panel, and a third anti-ultraviolet layer disposed on a side portion of the transparent display panel, and a cover member disposed outside the anti-ultraviolet member and including a first cover configured to cover the lower portion of the transparent display panel and a second cover configured to cover the upper portion of the transparent display panel.

### TECHNOLOGY FIELD

The present disclosure relates to a transparent display device. In more detail, the present disclosure relates to a transparent display device capable of improving quality and achieving rigidity.

### DISCUSSION OF RELATED ART

With advancement in information-oriented societies, demands for display devices that display images have increased in various forms. Recently, various types of display devices such as a liquid crystal display (LCD) device, a plasma display panel (PDP) device, a Quantum dot Light Emitting Display (QLED), and an organic light emitting display (OLED) device have been widely utilized.

In particular, the organic light emitting display devices are attracting attention as next-generation display devices because they are not only advantageous in terms of power consumption due to low-voltage operation, but also in terms of color reproduction, response speed, viewing angle, and contrast ratio.

In recent years, there has been active research on display devices that have a transmissive area to allow external light to pass through them, such that a background scene located behind the transparent display device or objects or images located on the rear surface of the transparent display device can be viewed through the transparent display device.

### SUMMARY OF THE INVENTION

### Problems to be Solved

The present disclosure is directed to providing a transparent display device that substantially obviates one or more problems due to limitations and disadvantages of the related art. An aspect of the present disclosure is directed to providing a transparent display device capable of improving brightness by increasing concentrating efficiency of light and improving quality by minimizing yellowing phenomenon at the edges of the display area to improve clarity, visibility, and readability.

Another aspect of the present disclosure is directed to providing a transparent display device that can improve rigidity by preventing breakage upon external impact.

Another aspect of the present disclosure is directed to providing a transparent display device capable of realizing ESG (Environment/Social/Governance) by increasing the lifespan of display devices and reducing the generation of greenhouse gases due to the manufacturing process for producing a display device.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

### Solution to Problems

To achieve these and other advantages and in accordance with the purpose of the disclosure, as embodied and broadly described herein, there is provided a transparent display device including a transparent display panel including a display area and a non-display area disposed outside of the display area, a first substrate and a second substrate bonded together, the first substrate and the second substrate including the display area, and the display area including a transmissive area and an emission area, an anti-ultraviolet member including a first anti-ultraviolet layer disposed on a lower portion of the transparent display panel, a second anti-ultraviolet layer disposed on an upper portion of the transparent display panel, and a third anti-ultraviolet layer disposed on a side portion of the transparent display panel, and a cover member disposed outside the anti-ultraviolet member and including a first cover configured to cover the lower portion of the transparent display panel and a second cover configured to cover the upper portion of the transparent display panel.

A plurality of optical patterns in the shape of lens can be disposed in the emission area.

The third anti-ultraviolet layer can be disposed on the outside of the transparent display panel to surround the plurality of optical patterns.

The third anti-ultraviolet layer can be disposed to surround at least three surfaces of the transparent display panel.

The third anti-ultraviolet layer can absorb or reflect at least a portion of light having a wavelength of 350 nm or less.

According to an aspect of the present disclosure, the cover member further comprises an adhesive layer disposed between the first cover and the second cover, the curved portion can be disposed an edge of the second cover, and the curved portion of the second cover can be coupled to the first cover through the adhesive layer.

### Effects of Invention

The transparent display device according to the present specification includes the upper and lower parts of the transparent display panel. By placing UV protection members on the and sides, reliability is ensured and the display area is protected. The transparent display device improves clarity, visibility, and readability by minimizing yellowing at the edges. The quality of the display device can be improved.

The transparent display device according to the present specification arranges an optical pattern in the light emitting area. Thus, light collection efficiency can be increased and luminance can be improved.

The transparent display device according to this specification secures rigidity and reliability and by improving the quality, and therefore the lifespan of transparent display devices can be increased. Because the manufacturing process for production can be reduced, this implements ESG (Environment/Social/Governance) by reducing the generation of greenhouse gases.

The effects that can be obtained in this specification are not limited to the effects mentioned above and other effects not mentioned are included in this specification from the description below.

### BRIEF DESCRIPTION OF THE DRAWINGS

FIG. 1 illustrates a transparent display device according to one or more embodiments of the present disclosure;

FIG. 2 is an exploded perspective view illustrating the transparent display device shown in FIG. 1;

FIG. 3 is cross-sectional view of one embodiment of the transparent display device shown in FIG. 1;

FIG. 4 illustrates the transparent display panel shown in FIG. 2;

FIG. 5 is a circuit diagram of subpixel applied to the transparent display panel shown in FIG. 4;

FIG. 6 is a perspective view illustrating a plurality of pixels according to one embodiment of an area A of transparent display device shown in FIG. 4;

FIG. 7 is cross-sectional view taken along line I-I′ of FIG. 6;

FIG. 8 is cross-sectional view of another embodiment of the transparent display device shown in FIG. 1;

FIG. 9 illustrates the transparent display device shown in FIG. 8;

FIG. 10 is cross-sectional view of another embodiment of the transparent display device shown in FIG. 1; and

FIG. 11 is cross-sectional view of another embodiment of the transparent display device shown in FIG. 1.

### SPECIFIC DETAILS FOR CARRYING OUT THE INVENTION

Hereinafter, the aspects of the present disclosure will be described in detail with reference to the accompanying drawings. The following aspects are provided by way of example so that spirit of the present disclosure can be sufficiently conveyed to those skilled in the art. Thus, the present disclosure can be embodied in different forms and should not be construed as limited to the aspects set forth herein.

A size and a thickness of device disclosed in the drawings, can be exaggerated for convenience. The scale of the components shown in the drawings are merely an example, thus the present disclosure is not limited to the illustrated scales. Like reference numerals refer to like elements throughout.

In the following description, when the detailed description of the relevant technology is determined to unnecessarily obscure the important point of the present disclosure, the detailed description will be omitted.

In a situation where “comprise,” “have,” and ‘include’ described in the present disclosure are used, another part can be added. The terms of a singular form can include plural forms unless referred to the contrary.

In describing a positional relationship, for example, when a position relation between two parts is described as “on,” “over,” “under,” and “next,” one or more other parts can be disposed between the two parts unless ‘just’ or ‘direct’ is used. The spatially relative terms “below,” “beneath,” “lower,” “above,” “upper,” and the like can be used to facilitate the description of the relationship of one element (or component) to another element (or component) as shown in the drawings. The spatially relative terms should be understood to include different orientations of an element in use or operation in addition to the orientations shown in the drawings. For example, an element described as “below” or “beneath” another element can be placed “above” another element when the elements shown in the drawings are inverted. Thus, the exemplary term “below” can include both downward direction and upward direction.

It will be understood that, although the terms “first,” “second,” “A,” “B,” “(a),” “(b),” etc. can be used herein to describe various elements of the present disclosure. These terms are only used to distinguish one element from another and the nature, sequence, order, or number of these elements should not be limited by these terms.

In assigning reference numerals to the components in each drawing, the same component can have the same numeral as far as possible, even if it is shown in different drawings. In addition, when the detailed description of the relevant technology is determined to unnecessarily obscure the important point of the present disclosure, the detailed description will be omitted.

Features of various aspects of the present disclosure can be partially or totally coupled to or combined with each other, and can be variously inter-operated with each other and driven technically as those skilled in the art can sufficiently understand. The aspects of the present disclosure can be carried out independently from each other or can be carried out together with a co-dependent relationship.

Hereinafter, with reference to the accompanying drawings and embodiments, a display device according to the present disclosure is described as follows.

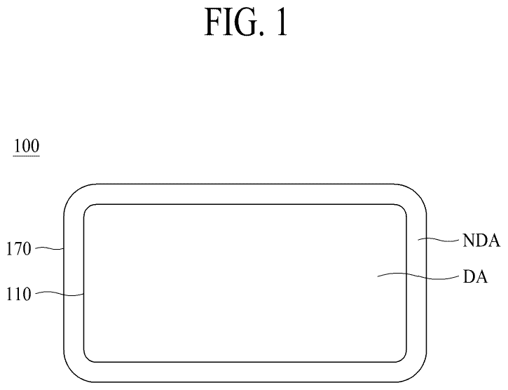

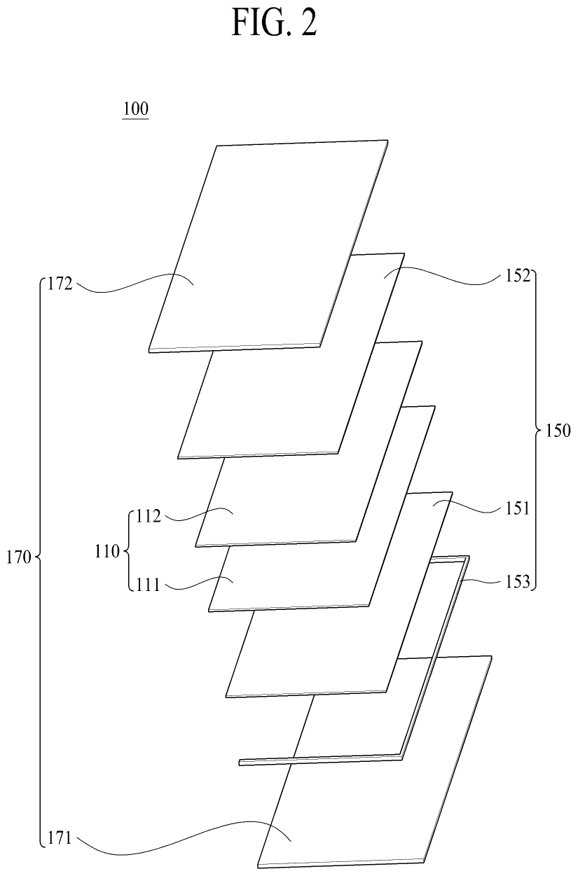

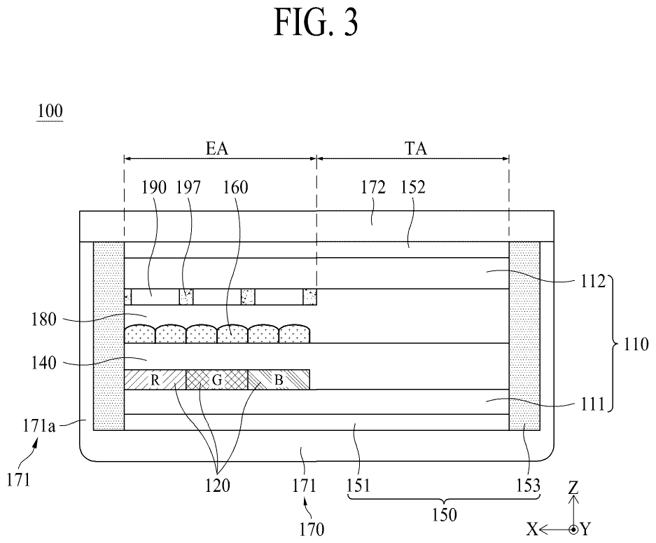

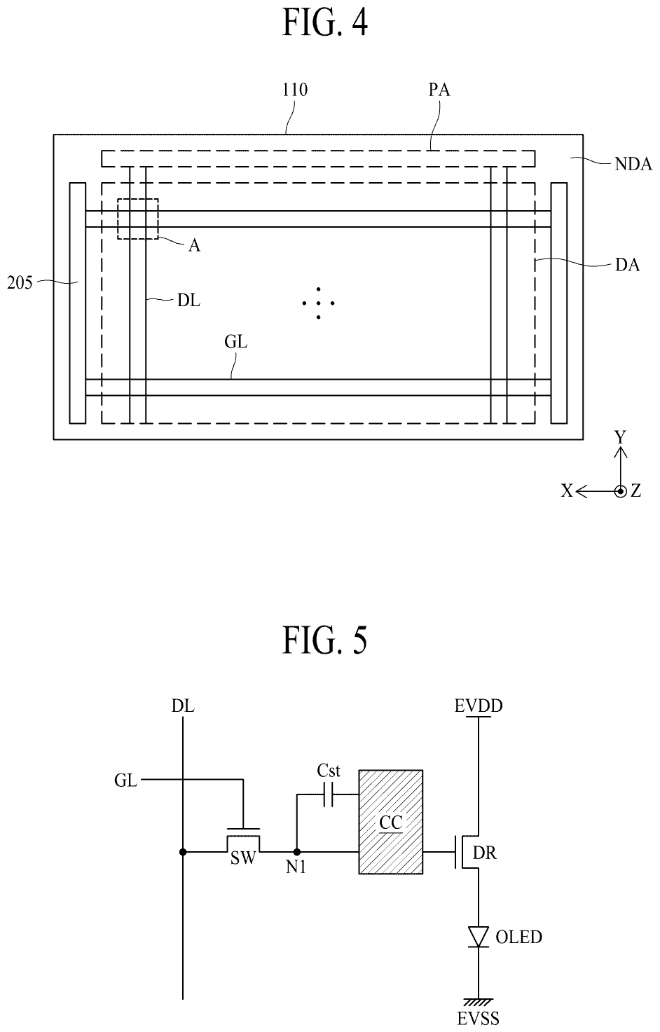

FIG. 1 illustrates a transparent display device according to one or more embodiments of the present disclosure, FIG. 2 is an exploded perspective view illustrating the transparent display device shown in FIG. 1, FIG. 3 is cross-sectional view of one embodiment of the transparent display device shown in FIG. 1, FIG. 4 illustrates the transparent display panel shown in FIG. 2, and FIG. 5 is a circuit diagram of subpixel applied to the transparent display panel shown in FIG. 4.

In the drawings, an X axis represents a direction parallel to a gate line, a Y axis represents a direction parallel to a data line, and a Z axis represents a height direction of the transparent display device.

Although a transparent display device 100 according to one or more embodiments of the present disclosure is described as an organic light emitting display apparatus (OLED), the transparent display device 100 can be implemented as a liquid crystal display (LCD) apparatus, a plasma display panel (PDP), a quantum dot light emitting display (QLED) apparatus, or an electrophoresis display apparatus and is not limited thereto.

Referring to FIGS. 1 to 3, the transparent display device 100 according to one or more embodiments of the present disclosure can be divided into a display area DA and a non-display area NDA outside the display area DA. The transparent display device 100 can include a transparent display panel 110, an anti-ultraviolet member 150 covering the transparent display panel 110, and a cover member 170 disposed outside the anti-ultraviolet member 150.

As shown in FIGS. 3 and 4, the transparent display panel device 100 can be divided a display area DA corresponding to the display area DA of the transparent display device 100 and a non-display area NDA corresponding to the non-display area NDA of the transparent display device 100.

The non-display area NDA can be formed in an edge area surrounding the display area DA. The non-display area NDA can include GIP part 205 which is a driving part for driving the pixel and the pad part PA.

The display area DA can include an emission area EA and a transmissive area TA. The emission area EA can include devices 120 comprising a plurality of pixels, and the can display images through the plurality of pixels. Each of the plurality of pixels can include a plurality of sub-pixels. The transmissive area TA is an area that transmits light incident from the outside, allowing viewing of an object or scenes that are located at a rear surface of the transparent display panel 110.

As shown in FIG. 5, one sub-pixel can include a switching transistor SW, a driving transistor DR, a capacitor Cst, a compensation circuit CC, and an organic light emitting diode OLED.

A first electrode (e.g., a drain electrode) of the switching transistor SW is electrically connected to a data line DL, and a second electrode (e.g., a source electrode) is electrically connected to a first node N1. A gate electrode of the switching transistor SW is electrically connected to a gate line GL. The switching transistor SW supplies a data signal supplied via the data line DL to the first node N1 in response to a scan signal supplied via the gate line GL.

The capacitor Cst is electrically connected to the first node N1 to charge the voltage applied to the first node N1.

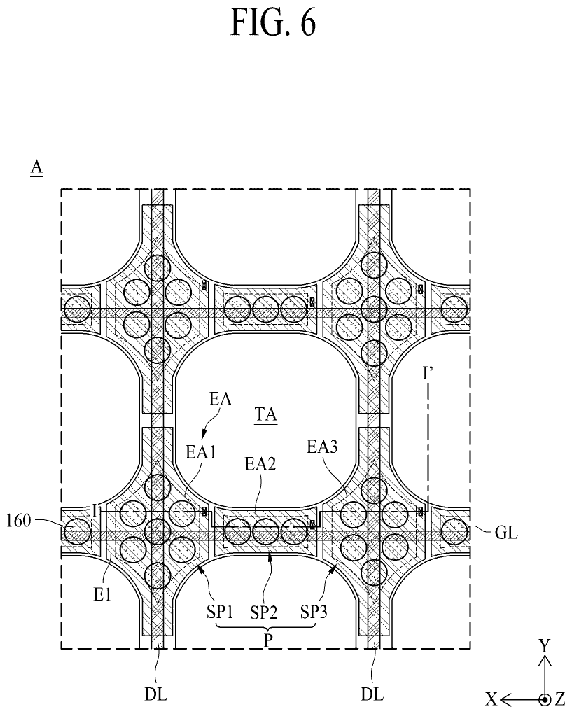

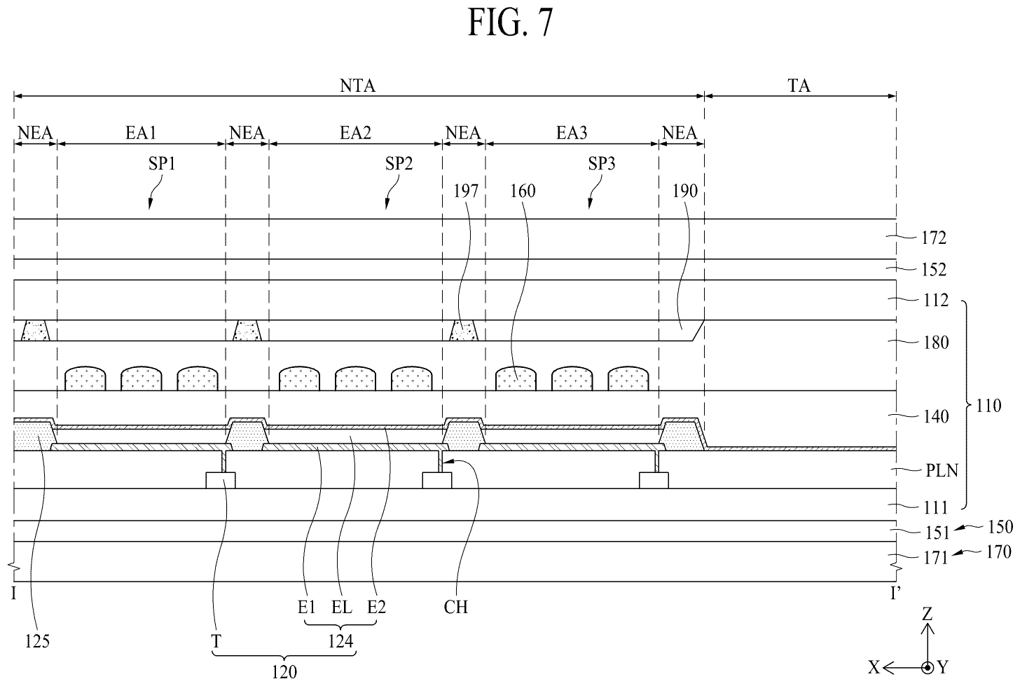

A first electrode (e.g., drain electrode) of the driving transistor DR is applied with a high potential driving voltage EVDD, and a second electrode (e.g., source electrode) is electrically connected to a first electrode (e.g., anode electrode, See E1 shown in FIGS. 6 and 7) of the organic light emitting diode OLED. The driving transistor DR can control the amount of driving current flowing to the organic light emitting diode OLED in response to a voltage applied to a gate electrode.

A semiconductor layer of the switching transistor SW and/or the driving transistor DR can include, but is not limited thereto, silicon, such as a-Si, poly-Si, or low-temperature poly-Si, or can include an oxide, such as IGZO (Indium-Gallium-Zinc-Oxide).

The organic light emitting diode OLED outputs light corresponding to the driving current. The organic light emitting diode OLED can output light corresponding to any one of the red color, the green color, and the blue color.

The organic light emitting diode OLED can include an anode electrode, a light emitting layer formed on the anode electrode, and a cathode electrode which applies common voltage. The light emitting layer can be implemented to emit the same color of light per pixel, such as white light, or can be implemented to emit different colors of light per pixel, such as red light, green light, or blue light.

The compensation circuit CC can be disposed in the pixel to compensate for a threshold voltage of the driving transistor DR. The compensation circuit CC can include one or more transistors. The compensation circuit CC can include one or more transistors and capacitors and can be configured in various ways depending on the compensation method. The pixel including the compensation circuit CC can have various structures, such as 3T1C, 4T2C, 5T2C, 6T1C, 6T2C, 7T1C, 7T2C, etc.

FIG. 6 is a perspective view illustrating a plurality of pixels according to one embodiment of an area A of transparent display device shown in FIG. 4 and FIG. 7 is cross-sectional view taken along line I-I′ of FIG. 6.

Referring FIGS. 6 and 7, the transparent display panel 110 according to an embodiment of the present disclosure includes a first substrate 111 and a second substrate 112 facing each other, and a plurality of pixels P capable of transmitting incident light or displaying images can be arranged in the display area DA.

The display area DA of the transparent display panel 110 includes a transmissive area TA and a non-transmissive area NTA. A pixel P in the display area DA can include a plurality of sub-pixels SP1, SP2, and SP3 and a transmissive area TA.

The non-transmissive area NTA can include a plurality of emission areas EA1, EA2, and EA3, and a non-emission area NEA between the emission areas EA1, EA2, and EA3. The plurality of emission areas EA1, EA2, and EA3 of the non-transmissive area NTA are areas that emit light through the devices 120 including an light emitting device layer 124 and a circuit device layer T to display images.

The emission area EA can include at least one of a plurality of emission areas EA1, EA2, and EA3 that emit different colors. For example, the plurality of emission areas EA1, EA2, and EA3 can include a red emission area, a green emission area, and a blue emission area, and can further include a white emission area. Alternatively, the plurality of emission areas EA1, EA2, EA3 can include at least two or more of the following emission areas: a red emission area, a green emission area, a blue emission area, a yellow emission area, a magenta emission area, and a cyan emission area. For instance, the red emission area is an area that emits red light, the green emission area is an area that emits green light, and the blue emission area is an area that emits blue light. The red emission area, the green emission area, and the blue emission area of the emission areas EA emit a predetermined light and correspond to a non-transmissive area NTA that does not transmit incident light.

Each of the plurality of emission areas EA1, EA2, and EA3 can have a different shape, and each of the plurality of emission areas EA1, EA2, and EA3 can have a polygonal shape.

Each of the plurality of emission areas EA1, EA2, and EA3 can have a different area size. A first electrode E1 can be disposed in each of the plurality of emission areas EA1, EA2, and EA3. The first electrode E1 disposed in each of the emission areas EA1, EA2, and EA3 can have a shape similar to the corresponding respective emission areas EA1, EA2, and EA3.

The size of each of the plurality emission areas EA1, EA2, and EA3 can be determined by considering the lifespan and light emitting efficiency of the light emitting device layer 124 disposed in each of emission areas EA1, EA2, and EA3.

For example, when a green light emitting device layer is disposed in the first emission area EA1, a red light emitting device layer is disposed in the second emission area EA2, and a blue light emitting device layer is disposed in the third emission area EA3, the blue light emitting device layer can have the shortest lifespan and the red light emitting device layer can have the longest lifespan given the same area size because shorter wavelengths of light have higher energy. Therefore, in order to achieve a uniform lifespan, the area size of the second emission area EA2 where the red emitting device layer is disposed can be set smaller than the area size of the first emission area EA1 where the green emitting device layer is disposed or the area size of the third emission area EA3 where the blue emitting device layer is disposed.

On the lines (e.g., DL) in the row direction or Y direction, the first emission area EA1 and the third emission area EA3 can be alternately arranged. On the lines (e.g. GL) in the column direction or X direction, the first emission area EA1 and the third emission area EA3 can be alternately arranged with the second emission area EA2 interposed therebetween.

The transmissive area TA is an area that transmits light incident from the outside, allowing viewing of objects or scenes located at a rear surface of the transparent display panel 110 or the first substrate 111.

FIG. 6 illustrates, but is not limited thereto, the transmissive area TA elongated in the data line direction (e.g., Y-axis direction) and the emission area EA elongated in the gate line direction (e.g., X-axis direction). In other words, both the transmissive area TA and the emission area EA can be elongated in the data line direction (e.g., Y-axis direction), or both the transmissive area TA and the emission area EA can be elongated in the gate line direction (e.g., X-axis direction).

The transmissive area TA can be arranged to have a polygonal shape, but embodiments are not limited thereto. Since the transmissive area TA of the transparent display panel 110 according to the present disclosure can have a polygonal shape and opposite sides of the adjacent transmissive areas TA can not be fully parallel to each other, the parallel regularity and periodicity of the transmissive areas TA can be avoided, thereby mitigating the diffraction phenomenon of light.

Specifically, as shown in FIG. 6, the transmissive area TA of the transparent display panel 110 according to the present disclosure can have an octagonal shape including a round or curved shape, or rounded corners. When the transmissive area TA has the octagonal shape including the round or curved shape, transmissive areas TA that are adjacent to each other in a row direction or a column direction do not have opposing sides that are fully parallel to each other in at least one of the row or column, which can mitigate diffraction of light compared to transmissive areas that have opposing sides that are parallel in both the row and the column.

As shown in FIG. 7, the above described transmissive area TA and non-transmissive area NTA are disposed on first substrate 111 and second substrate 112 facing each other to transmit light incident from the outside or to display images by emitting internal light.

The first substrate 111 is made of a transparent material having a transmittance of 30% or more so that a viewer looking at the second substrate 112 can see scenes located at the rear surface of the first substrate 112. The first substrate 111 can be a transparent plastic film, a transparent glass substrate, or a transparent silicon wafer substrate formed using a semiconductor process.

The second substrate 112 can be an encapsulation substrate for protecting and sealing various elements on the first substrate 111. Since the scenes located at the rear surface of the first substrate 111 have to be visible through the second substrate 112, the second substrate 112 is made of a transparent material with a transmittance of 30% more. The second substrate 112 can be a transparent plastic film, a transparent glass substrate, or a transparent encapsulation film. The second substrate 112 can have the same transparency as the first substrate 111, or can have a different transparency.

The first substrate 111 can be formed larger than the second substrate 112. This can cause a portion of the first substrate 111 to be exposed without being covered by the second substrate 112. The first substrate 111 and the second substrate 112 can be bonded together to form the transparent display panel 100.

A circuit device layer T is disposed on the first substrate 111 between the first and second substrates 111 and 112. Circuit elements including various signal lines, thin-film transistor, and capacitor are disposed in the circuit device layer T for each pixel. The signal lines can include gate lines, data lines, driving power lines, common power lines, and reference lines. The thin film transistor can include the switching thin film transistor, the driving thin film transistor, and the sensing thin film transistor.

A planarization film PLN is disposed on the circuit device layer T to planarize the top of the circuit device layer T.

A light emitting device layer 124 is disposed on the planarization film PLN. The light emitting device layer 124 is electrically connected to the circuit device layer T below. The light emitting device layer 124 includes a plurality of first electrodes E1, a light emitting layer EL, and a second electrode E2.

The first electrode E1 can include a metal material which is high in reflectivity. For example, the first electrode E1 can be a multi-layer structure such as a stacked structure (titanium/aluminum/titanium (Ti/Al/Ti)) of Al and Ti, a stacked structure (indium tin oxide/Al/indium tin oxide (ITO/Al/ITO)) of Al and ITO, an APC (silver/palladium/copper) alloy, or a stacked structure (ITO/APC/ITO) of an APC alloy and ITO, or can include a single-layer structure including one material or two or more alloy materials selected from among Ag, Al, molybdenum Mo, gold Au, magnesium Mg, calcium Ca, and barium Ba.

The light emitting layer EL can be provided on the first electrode E1. The light emitting layer EL can be an organic light emitting layer including an organic material. In this situation, the light emitting layer EL can include a hole transporting layer, an organic light emitting layer, and an electron transporting layer.

When voltages are applied to the first electrode E1 and the second electrode E2, holes and electrons are transported to the organic light emitting layer through the hole transporting layer and the electron transporting layer, respectively, and they can be combined with each other in the organic light emitting layer to emit light.

The light emitting layer EL can include a red light emitting layer emitting red light, a green light emitting layer emitting green light, and a blue light emitting layer emitting blue light. The red light emitting layer, the green light emitting layer, and the blue light emitting layer can be patterned on the first electrode E1 by sub-pixels SP1, SP2, and SP3. The red light emitting layer can be patterned in a red pixel, the green light emitting layer can be patterned in a green pixel, and the blue light emitting layer can be patterned in a blue pixel. However, the present disclosure is not limited thereto. Alternatively, the light emitting layer EL can be a white light emitting layer emitting white light. In this situation, the light emitting layer EL can be a common layer which is formed in the sub-pixels SP1, SP2, and SP3 in common.

The light emitting layer EL can be provided in a tandem structure of two or more stacks. Each of the stacks can include the hole transporting layer, at least one organic light emitting layer, and the electron transporting layer. A charge generating layer can be provided between the stacks.

The second electrode E2 can be provided over the light emitting layer EL. The second electrode E2 can be provided over the entire area of the pixel P. The second electrode E2 can be provided in the transmissive area TA as well as in the non-transmissive area NTA including the emission area EA, but is not limited thereto.

The second electrode E2 can be provided in only the non-transmissive area NTA including the emission area EA and can be absent in the transmissive area TA, for enhancing a transmittance. The second electrode E2 can be a common layer provided in the pixels P and the same voltage is applied.

The second electrode E2 can include a transparent conductive material TCO, such as indium tin oxide ITO or indium zinc oxide IZO, or a semi-transmissive conductive material such as magnesium Mg, silver Ag, or an alloy of Mg and Ag, which transmit light. When the second electrode E2 is formed of the semi-transmissive conductive material, emission efficiency can be increased by a micro-cavity.

The light emitting device layer 124 can be a pixel array layer in which the pixels P are formed, and the area in which the light emitting device layer 124 is formed can be defined as a display area DA. Sub-pixels SP1, SP2, and SP3 within the display area DA can be partitioned or defined by a bank 125.

The bank 125 can be provided at an end of the first electrode E1. Therefore, adjacent first electrodes E1 can be electrically insulated from each other, and emission efficiency can be prevented from being reduced by the concentration of a current on the end of the first electrode E1.

The bank 125 can form an opening portion to expose the planarization film PLN in the transmissive area TA. The bank 125 can be absent in the transmissive area TA, thereby enhancing a transmittance of the transmissive area TA. The bank 125 can extend from an end of one first electrode E1 to an end of another first electrode E1 disposed adjacent thereto.

The encapsulation layer 150 can be provided over the light emitting device layer 124. The encapsulation layer 126 can prevent penetration of oxygen or water into the light emitting device layer 124. The encapsulation layer 150 can include at least one inorganic film and at least one organic film. The encapsulation layer 150 can be formed in a structure where the inorganic film and the organic film are alternately stacked, but is not limited thereto.

A plurality of optical patterns 160 are disposed on the encapsulation layer 150 in the transmissive area TA. The plurality of optical patterns 160 are disposed to correspond to the emission areas EA1, EA2, and EA3 of the non-transmissive area NTA. The plurality of optical patterns 160 are disposed in each of the emission areas EA1, EA2, and EA3 to increase the extraction efficiency of the light generated by the light emitting element layer 124 of each of sub-pixels SP1, SP2, and SP3.

Specifically, when light generated by the light emitting device layer 124 of each of the sub-pixels SP1, SP2, and SP3 passes through the encapsulation layer 140 toward the second substrate 112, the light can pass through the plurality of optical patterns 160. The optical patterns 160 can cause the light to be refracted, multiple reflected or diffusely reflected, and thus concentrated or focused, thereby improving the extraction efficiency of the transparent display device 100.

Accordingly, the transparent display device 100 according to the present disclosure can prevent light emitted from the light emitting device layer 124 from being trapped inside the transparent display device 100 by the plurality of optical patterns 160 disposed in the emission areas EA and improve light extraction to realize high brightness. Furthermore, the transparent display device 100 according to the present disclosure can reduce the area of the emissions EA for the same brightness, and thus the area of the transmissive area TA can be enlarged, thereby simultaneously improving the transmittance of the transmissive area TA.

Thus, the transparent display device 100 according to the present disclosure can improve brightness to reduce power consumption, thereby realizing a low-power transparent display device 100.

The optical patterns 160 on the encapsulation layer 150 can have a convex shape or a curved portion from the upper surface of the encapsulation layer 150. The optical patterns 160 can have convex shape including a cylinder shape, or the optical patterns 160 can have a semi-cylindrical base having a predetermined height and a hemispherical lens shape on the semi-cylindrical base.

As shown in FIG. 7, the plurality of optical patterns 160 are disposed within the emission area EA. The plurality of optical patterns 160 can be disposed to space apart from each other. In this case, a flat surface can be disposed between each of the optical patterns 160. The flat surface disposed between each of the optical patterns 160 can be a top surface of the encapsulation layer 140.

The optical patterns 160 can be a pattern including a hemispherical transparent insulating material. The optical patterns 160 can be made of an organic insulating material. The optical patterns 160 can be made of an organic insulating material such as photo acrylic or glass.

An optical insulating layer 180 is disposed on the encapsulation layer 150 to cover the optical patterns 160.

The optical insulating layer 180 is disposed between the optical patterns 160 and the second substrate 112 to mitigate a step difference caused by the optical patterns 160. The first substrate 111 having the optical insulating layer 180 can have a flat top surface because a top surface of the first substrate 111 is covered by the optical insulating layer 180 to be flattened even if the optical patterns 160 having the convex shape or the curved portion are disposed on the encapsulation layer 140.

If the top surface of the first surface 111 is curved due to the optical patterns 160, a haze phenomenon can increase. However, in the present disclosure, the optical insulating layer 180 can planarize the top of the optical patterns 160 to prevent the haze phenomenon from increasing.

The optical insulating layer 180 can bond or join the second substrate 112 to the first substrate 111 on which the circuit device layer T, the light emitting device layer 124, and the encapsulation layer 150 are formed, and seal the inside of the first substrate 111 and the second substrate 112.

The optical insulating layer 180 can comprise an organic insulating material. The optical insulating layer 180 can be made of photo acryl, benzocyclobutene BCB, polyimide PI, or polyamide PA.

The color filter 190 can further be disposed between the optical insulating layer 180 and the second substrate 112. The color filter 190 can be disposed on one surface of the second substrate 112 facing the first substrate 111. The color filter 190 can be disposed to correspond to each of the emission areas EA1, EA2, and EA3 per sub-pixels SP1, SP2, and SP3. The color filter 190 can include a red color filter disposed to correspond to an emission area EA of the red sub-pixel, a green color filter disposed to correspond to an emission area EA of the green sub-pixel, and a blue color filter disposed to correspond to an emission area EA of the blue sub-pixel.

The color filter 190 provided in each of sub-pixels SP1, SP2, and SP3 can be formed to cover the emission area EA. That is, the color filter 190 can have the same area size as that of a minimum size of emission area EA or can have an area size which is larger than that of the emission area EA.

The color filter 190 can be disposed on one surface of the second substrate 112 and then bonded to the first substrate 111, or the bonding process can be omitted by finishing the upper part with a COE (color-filter on encap) method, where a low-temperature color filter process is applied to the substrate. When the color filter 190 is disposed in the COE method, the bonding process can be omitted, thus avoiding damage to an organic film layer, which is vulnerable to high temperatures.

In the transparent display panel 110 according to one or more embodiments of the present disclosure, the color filter 190 can be formed on the second substrate 112 and light incident from the outside can be prevented from being reflected by the electrodes E1 and E2 inside the transparent display panel 110. That is, the transparent display device 100 according to one or more embodiments of the present disclosure can decrease an external light reflectance without reducing a transmittance and omit the use of a polarizer.

Since the transparent display device 100 according to the present disclosure cannot use the polarizer, carbon emissions that can be generated by the manufacturing process for producing the polarizer can be reduced and the generation of greenhouse gases can be reduced, thereby implementing ESG (Environment/Social/Governance).

A black matrix 197 can be provided between the color filters 190. The black matrix 197 can be disposed in a pattern in the non-emission area NEA per sub-pixels SP1, SP2, and SP3. The black matrix 197 can be arranged to correspond to the bank 125. The black matrix 197 can be disposed to correspond to the non-emission area NEA to prevent light incident from the outside from being reflected by a plurality of lines inside the transparent display panel 110.

The black matrix 197 can be disposed between each of the sub-pixels SP1, SP2, and SP3 in the non-transmissive area NTA. The black matrix 197 can be disposed between the sub-pixels SP1, SP2, and SP3 to prevent color mixing between adjacent sub-pixels SP1, SP2, and SP3.

The black matrix 197 can include a light-absorbing material, such as a black dye for absorbing all light within a visible light wavelength band. Further, the black matrix 197 can comprise a stacked structure of neighboring color filters 190 of adjacent sub-pixels. For example, the black matrix 197 can be composed of a stacked structure of the red color filter, the green color filter, and the blue color filter disposed correspondingly to each of the sub-pixels SP1, SP2, and SP3.

The black matrix 197, which comprises a stacked structure of the red color filter, the green color filter, and the blue color filter, can be disposed between the pixels P, which are defined by a collection of at least three sub-pixels SP1, SP2 and SP3.

Since the black matrix 197, which comprises the stacked structure of the red color filter, the green color filter, and the blue color filter, can be disposed together when the color filters are formed, a separated process for disposing the black matrix 197 can be omitted to can be shorten the production process time, thereby reducing the generation of greenhouse gases due to the manufacturing process, and thereby implementing ESG.

Although the transparent display panel 110 is illustrated as implemented in a top emission method, it is not limited thereto and can also be implemented in a bottom emission method. In the top emission method, light emitted from the light emitting layer EL is directed toward the second substrate 112, so that the circuit device layer T can be provided widely below the bank 125 and the first electrode E1. Therefore, the top emission method has the advantage of a larger design area for the circuit device layer T compared to the bottom emission method.

As described above, each of the pixels P of the transparent display device 100 including the transparent display panel 110 according to one or more embodiments of the present disclosure includes at least one the optical pattern 160 disposed in the emission area EA displaying images. As a result, the transparent display panel 110 according to one or more embodiments of the present disclosure or the transparent display device 100 equipped with the transparent display panel 110 can improve the transmittance of the transmissive areas TA through which an object or scene located on the rear surface can be seen, while at the same time improving the brightness of the light emitted from the emission area EA.

As shown in FIG. 3, the cover member 170 is disposed on the outside of the transparent display panel 110. The cover member 170 can be disposed to surround the exterior of the transparent display panel 110 and is exposed to the outside of the transparent display panel 110 to protect the transparent display panel 110 from external impacts or the like. The cover member 170 can be coupled to the transparent display panel 110 via the anti-ultraviolet member 150.

The cover member 170 has a larger area than the transparent display panel 110 and is disposed on the front surface and rear surface of the transparent display panel 110. The cover member 170 accommodates the transparent display panel 110 inside of the cover member 170. The cover member 170 has a curved portion 171a to cover or accommodate the transparent display panel 110.

The cover member 170 includes a first cover 171 that accommodates the transparent display panel 110 and a second cover 172 through which an image is visible.

Specifically, the first cover 171 is disposed below the first substrate 111 of the transparent display panel 110 with a larger area than the first substrate 111. The second cover 172 is disposed over the second substrate 112 of the transparent display panel 110 with an area larger than the second substrate 112. The first cover 171 and the second cover 172 are disposed to face each other with the transparent display panel 110 between them.

The cover member 170 can include the curved portion 171a. Specifically, the first cover 171 of the cover member 170 includes the curved portion 171a that accommodates the transparent display panel 110 and covers the side surfaces of the first substrate 111 and the second substrate 112. The curve portion 171a is a portion of the first cover 171 covering an edge portion of the first substrate 111 of the transparent display panel 110 that is bent in a direction toward the second substrate 112 (or Z direction) to extend in the direction toward the second substrate 112 (or Z direction).

One end of the curved portion 171a can be extended to at least a top surface of the second substrate 112 to cover the side surface of the second substrate 112. The curved portion 171a can surround the side surface of the transparent display panel 110 and be parallel to the side surface of the transparent display panel 110.

A predetermined internal space can be defined between the first cover 171 and the rear surface of the transparent display panel 110. The anti-ultraviolet member 150 can be disposed in the predetermined internal space between the first cover 171 and the rear surface of the transparent display panel 110. Specifically, a first anti-ultraviolet layer 151 can be disposed in the predetermined internal space between the first cover 171 and the rear surface of the transparent display panel 110.

Further, a predetermined internal space can be defined between the inner side of the curved portion 171a of the first cover 171 and the side surface of the transparent display panel 110. The anti-ultraviolet member 150 can be disposed in the predetermined internal space between the curved portion 171a and the side surface of the transparent display panel 110. Specifically, a third anti-ultraviolet layer 153 can be disposed in the predetermined internal space between the curved portion 171a and the side surface of the transparent display panel 110.

The first cover 171 contacts with the anti-ultraviolet member 150 (the first anti-ultraviolet layer 151 or the third anti-ultraviolet layer 153) and can be coupled to the transparent display panel 110 by the anti-ultraviolet member 150 (the first anti-ultraviolet layer 151 or the third anti-ultraviolet layer 153).

The first cover 171 accommodates the transparent display panel 110 therein and is coupled to surround the rear surface and side surface of the transparent display panel 110 through the anti-ultraviolet member 150, thereby protecting the rear surface and side surface of the transparent display panel 110 from external impacts, etc.

In the present disclosure, the meaning of the word “cover” includes a meaning of covering an object by directly contacting the object, a meaning of covering the object with an intervening medium, and a meaning of covering the object from above or from below.

The second cover 172 is disposed on the second substrate 112 of the transparent display panel 110 to be coupled the first cover 171. A rear surface of an edge of the second cover 172 can be coupled with one end of the curved portion 171a of the first cover 171. The second cover 172 and the first cover 171 can be coupled near the top surface of the second substrate 112 of the transparent display panel 110. A side surface of the second cover 172 can be disposed to correspond to an outer side surface of the first cover 171 or an outer side portion of the curved portion 171a.

A predetermined internal space can be defined between the second cover 172 and the top surface of the transparent display panel 110. The anti-ultraviolet member 150 can be disposed in the predetermined internal space between the second cover 172 and the top surface of the transparent display panel 110. Specifically, a second anti-ultraviolet layer 152 can be disposed in the predetermined internal space between the second cover 172 and the top surface of the transparent display panel 110. The second cover 172 contacts with the anti-ultraviolet member 150 (or the second anti-ultraviolet layer 152) and can be coupled to the transparent display panel 110 by the anti-ultraviolet member 150 (or the second anti-ultraviolet layer 152).

The second cover 172 covers the top surface and edges of the transparent display panel 110 and is coupled to the transparent display panel 110 through the anti-ultraviolet member 150, thereby protecting the top surface and edges of the transparent display panel 110 from external impacts, etc.

The first cover 171 and the second cover 172 can include a transparent glass or transparent plastic material. The first cover 171 and the second cover 172 can be a film-type including an organic material having impact-resistance and light-transmissive, for example, polymethylmethacrylate PMMA, polycarbonate PC, cycloolefin polymer COP, polyethylene terephthalate PET, polyimide PI, or polyaramid PA, and can include an inorganic material such as thin glass, sapphire, etc.

The anti-ultraviolet member 150 is disposed between the cover member 170 and the transparent display panel 110. The anti-ultraviolet member 150 is disposed to surround the transparent display panel 110 to absorb or block external ultraviolet rays, thereby preventing ultraviolet rays from entering into the transparent first substrate 111 and the transparent second substrate 112 of the transparent display panel 110.

The anti-ultraviolet member 150 includes the first anti-ultraviolet layer 151 disposed on the rear surface of the transparent display panel 110, the second anti-ultraviolet layer 152 disposed on the top surface of the transparent display panel 110, and the third anti-ultraviolet layer 153 disposed on the side surface of the transparent display panel 110.

The first anti-ultraviolet layer 151 is disposed on the rear surface of the first substrate 111 of the transparent display panel 110, and is disposed to cover the entire rear surface of the first substrate 111.

The first anti-ultraviolet layer 151 can include a transparent organic material. The first anti-ultraviolet layer 151 can include a transparent resin material including an ultraviolet-blocking material. The first anti-ultraviolet layer 151 can include an ultraviolet absorber or an ultraviolet blocker in the transparent resin layer.

The first anti-ultraviolet layer 151 can further include an adhesive material in a transparent resin layer containing the ultraviolet absorber or the ultraviolet blocker, thereby allowing the transparent display panel 110 and the cover member 170 to be more stably coupled.

The first anti-ultraviolet layer 151 can protect the transparent display panel 110 by absorbing or blocking at least a portion of light having a wavelength corresponding to the visible light range or less. Specifically, the first anti-ultraviolet layer 151 can block light from entering into the transparent display panel 110 by absorbing or reflecting at least the portion of light having a wavelength of 350 nm or less.

The second anti-ultraviolet layer 152 is disposed on the top surface of the second substrate 112 of the transparent display panel 110 and is disposed to cover the entire top surface of the second substrate 112.

The second anti-ultraviolet layer 152 can include a transparent organic material. The second anti-ultraviolet layer 152 can include a transparent resin material including an ultraviolet-blocking material. The second anti-ultraviolet layer 152 can include an ultraviolet absorber or an ultraviolet blocker in the transparent resin layer.

The second anti-ultraviolet layer 152 can further include an adhesive material in a transparent resin layer containing the ultraviolet absorber or the ultraviolet blocker, thereby allowing the transparent display panel 110 and the cover member 170 to be more stably coupled.

The second anti-ultraviolet layer 152 can protect the transparent display panel 110 by absorbing or blocking at least a portion of light having a wavelength corresponding to the visible light range or less. Specifically, the second anti-ultraviolet layer 152 can block light from entering into the transparent display panel 110 by absorbing or reflecting at least the portion of light having a wavelength of 350 nm or less.

The third anti-ultraviolet layer 153 can be disposed on the side surface of the first substrate 111 and the second substrate 112 of the transparent display panel 110 between the first cover 171 and the second cover 172. As shown in FIG. 2, the third anti-ultraviolet layer 153 can be disposed to surround at least three side surfaces of the transparent display panel 110.

In the transparent display device 100, the scenes located at rear surface of the transparent display device 100 have to be seen. However, when the driving parts such as a timing control board for driving the transparent display panel 110 are disposed on the rear surface of the display area DA of the transparent display panel 110, the driving parts can reduce the transparency of the transparent display device 100, so the driving parts have to be disposed on the outside of the transparent display panel 110. The third anti-ultraviolet layer 153 can be disposed to surround at least three side surfaces of the transparent display panel 110, except for one side surface of the transparent display panel 110 for connecting the driving parts disposed on the outside of the transparent display panel 110 with the transparent display panel 110.

The third anti-ultraviolet layer 153 can be further disposed on an area excluding only the connection portion for connecting the driving parts to the transparent display panel 110 on one side surface of the transparent display panel 110.

The third anti-ultraviolet layer 153 is disposed on the side surface of the transparent display panel 110 and is disposed on the outside of the transparent display panel 110 to cover at least one of the optical pattern 160, the optical insulating layer 180, and the color filter 190 inside the transparent display panel 110. The third anti-ultraviolet layer 153 can be disposed on the outside of the transparent display panel 110 to surround the optical pattern 160 disposed in the emission area EA inside the transparent display panel 110 on at least three surfaces of the transparent display panel 110.

The third anti-ultraviolet layer 153 can absorb or reflect ultraviolet rays to prevent ultraviolet rays from entering into the transparent through first substrate 111 and the transparent second substrate 112.

Specifically, the third anti-ultraviolet layer 153 can absorb or reflect external ultraviolet rays that can enter into the transparent display panel 110 from the side surface of the transparent display panel 110. Through this, it is possible to prevent yellowing phenomenon from occurring when ultraviolet rays reacts with the optical pattern 160 inside the transparent display panel 110.

The third anti-ultraviolet layer 153 can include a transparent organic material. The third anti-ultraviolet layer 153 can include a transparent resin material including an ultraviolet-blocking material. The third anti-ultraviolet layer 153 can include an ultraviolet absorber or an ultraviolet blocker in the transparent resin layer.

The third anti-ultraviolet layer 153 can further include an adhesive material in a transparent resin layer containing the ultraviolet absorber or the ultraviolet blocker, thereby allowing the transparent display panel 110 and the cover member 170 to be more stably coupled.

The third anti-ultraviolet layer 153 can block ultraviolet rays from entering into the transparent display panel 110 by absorbing or reflecting at least the portion of light having a wavelength corresponding to the visible light range or less, thereby protecting the transparent display panel 110.

Specifically, the third anti-ultraviolet layer 153 can block light from entering into the transparent display panel 110 by absorbing or reflecting at least the portion of light having a wavelength of 350 nm or less.

The first anti-ultraviolet layer 151, the second anti-ultraviolet layer 152, and the third anti-ultraviolet layer 153 can be made of the same material.

The anti-ultraviolet member 150 can be disposed to surround the rear surface, top surface, and at least three side surfaces of the transparent display panel 110 between the transparent display panel 110 and the cover member 170 to prevent external foreign substances, such as moisture or oxygen, from penetrating into the transparent display panel 110, thereby improving the reliability of the transparent display panel 110. Furthermore, the anti-ultraviolet member 150 can absorb an impact applied to the transparent display panel 110 or buffer an external impact to protect the transparent display panel 110.

The anti-ultraviolet member 150 can include a first anti-ultraviolet layer 151 and a second anti-ultraviolet layer 152 on the rear surface and top surface of the transparent display panel 110 to absorb or block ultraviolet rays from the outside of the transparent display panel 110 to prevent ultraviolet rays from entering into the transparent first substrate 111 and the transparent second substrate 112.

In general, a transparent display device is transparent, unlike a general display device, so that external light can pass through the inside of the transparent display device. The transparent display panel 110 according to the present disclosure includes the optical patterns 160 including organic matter therein, and the third anti-ultraviolet layer 153 of the anti-ultraviolet member 150 is disposed to surround the optical patterns 160 inside the transparent display panel 110 from outside to absorb or reflect external ultraviolet rays, so that an interaction of the external ultraviolet rays and the optical patterns 160 in the display area DA can be blocked and yellowing phenomenon caused by oxidation reactions in the display area DA of the transparent display panel 110 can be prevented from occurring.

In particular, the third anti-ultraviolet layer 153 can block ultraviolet rays from entering into the edges of the display area DA where external ultraviolet rays can first reach, so that yellowing phenomenon at the edges of the display area DA can be minimized.

The anti-ultraviolet member 150, including the third anti-ultraviolet layer 153, can be disposed to surround not only the top and rear surfaces of the transparent display panel 110 but also the edges of the transparent display panel 110. Accordingly, when a user uses the transparent display device 100 in an external environment, external ultraviolet rays can be prevented from entering into the transparent display panel 110, thereby minimizing yellowing phenomenon, thereby improving the clarity, visibility, and readability of the transparent display device 100.

The transparent display device 100 can include the cover member 170 of various embodiments for accommodating the transparent display panel 110 in an internal space. In the following description, redundant descriptions of the same reference numerals described above will be omitted, and the description will focus on the cover member of various embodiments that can improve the transparency and reliability of the transparent display device 100.

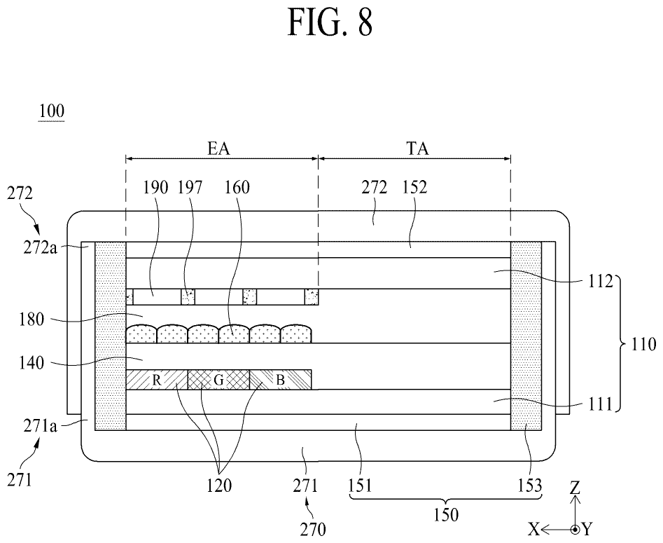

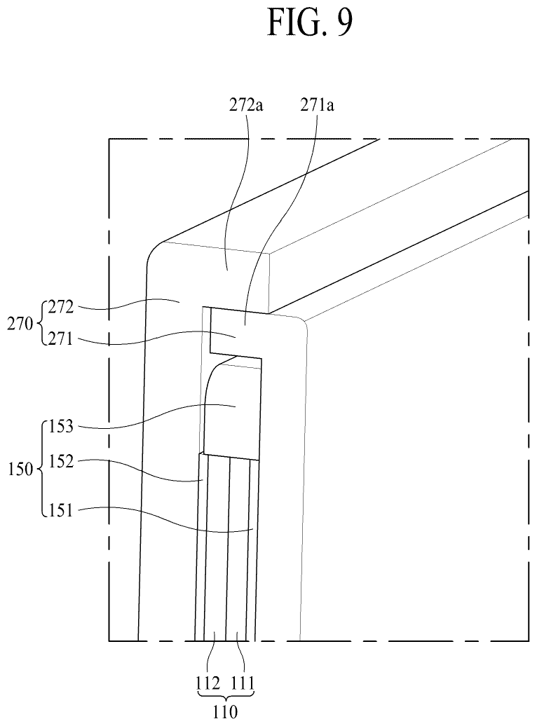

FIG. 8 is cross-sectional view of another embodiment of the transparent display device shown in FIG. 1 and FIG. 9 illustrates the transparent display device shown in FIG. 8.

Referring FIGS. 1, 8, and 9, the transparent display device 100 can be divided into a display area DA and a non-display area NDA outside the display area DA. The transparent display device 100 can include a transparent display panel 110, an anti-ultraviolet member 150 covering the transparent display panel 110, and a cover member 270 disposed outside the anti-ultraviolet member 150.

The cover member 270 is coupled to the transparent display panel 110 via the anti-ultraviolet member 150 disposed between the cover member 270 and the transparent display panel 110.

The cover member 270 is disposed on the front surface and rear surface of the transparent display panel 110. The cover member 270 accommodates the transparent display panel 110 inside of the cover member 270. The cover member 270 includes a first cover 271 that accommodates the transparent display panel 110 and a second cover 272 through which an image is visible. The first cover 271 and the second cover 272 are disposed to face each other with the transparent display panel 110 between them.

The first cover 271 accommodates the transparent display panel 110 and includes a first curved portion 271a that covers the side surfaces of the first substrate 111 and the second substrate 112. The first curved portion 271a is a portion of the first cover 271 covering an edge portion of the first substrate 111 of the transparent display panel 110 that is bent in a direction toward the second substrate 112 (or Z direction) to extend in the direction toward the second substrate 112 (or Z direction).

One end of the first curved portion 271a can be extended to at least a top surface of the second substrate 112 to cover the side surface of the second substrate 112. The first curved portion 271a can surround the side surface of the transparent display panel 110 and be parallel to the side surface of the transparent display panel 110.

A predetermined internal space can be defined between the first cover 271 and the rear surface of the transparent display panel 110. The anti-ultraviolet member 150 can be disposed in the predetermined internal space between the first cover 271 and the rear surface of the transparent display panel 110. Specifically, a first anti-ultraviolet layer 151 can be disposed in the predetermined internal space between the first cover 271 and the rear surface of the transparent display panel 110.

Further, a predetermined internal space can be defined between the inner side of the first curved portion 271a of the first cover 271 and the side surface of the transparent display panel 110. The anti-ultraviolet member 150 can be disposed in the predetermined internal space between the curved portion 271a and the side surface of the transparent display panel 110. Specifically, a third anti-ultraviolet layer 153 can be disposed in the predetermined internal space between the first curved portion 271a and the side surface of the transparent display panel 110.

The first cover 271 contacts with the anti-ultraviolet member 150 (the first anti-ultraviolet layer 151 or the third anti-ultraviolet layer 153) and can be coupled to the transparent display panel 110 by the anti-ultraviolet member 150 (the first anti-ultraviolet layer 151 or the third anti-ultraviolet layer 153).

The first cover 271 accommodates the transparent display panel 110 therein and is coupled to surround the rear surface and side surface of the transparent display panel 110 through the anti-ultraviolet member 150, thereby protecting the rear surface and side surface of the transparent display panel 110 from external impacts, etc.

The second cover 272 is disposed on the second substrate 112 of the transparent display panel 110 to be coupled the first cover 271. The second cover 272 includes a second curved portion 272a with curved edge. The second curved portion 272a can be disposed parallel to the first curved portion 271a, and the second curved portion 272a is coupled to the first curved portion 271a. An inner portion of the second curved portion 272a is coupled to an outer portion of the first curved portion 271a.

The second cover 272 covers the top surface and side surface of the transparent display panel 110 and is coupled to the transparent display panel 110 through the anti-ultraviolet member 150, thereby protecting the top surface and side surface edges of the transparent display panel 110 from external impacts, etc.

The first cover 271 and the second cover 272 can include a transparent glass or transparent plastic material. The first cover 271 and the second cover 272 can be a film-type including an organic material having impact-resistance and light-transmissive, for example, polymethylmethacrylate PMMA, polycarbonate PC, cycloolefin polymer COP, polyethylene terephthalate PET, polyimide PI, or polyaramid PA, and can include an inorganic material such as thin glass, sapphire, etc.

The anti-ultraviolet member 150 is disposed between the cover member 270 and the transparent display panel 110. The anti-ultraviolet member 150 is disposed to surround the transparent display panel 110 to absorb or block external ultraviolet rays, thereby preventing ultraviolet rays from entering into the transparent first substrate 111 and the transparent second substrate 112 of the transparent display panel 110.

The third anti-ultraviolet layer 153 can be disposed between the side surface of the transparent display panel 110 and the first curved portion 271a and/or the second curved portion 272a. The third anti-ultraviolet layer 153 can be disposed to surround the optical pattern 160 inside the transparent display panel 110 on the side surface of the transparent display panel 110. The third anti-ultraviolet member 150 can absorb or reflect ultraviolet rays, thereby preventing external ultraviolet rays from entering into the transparent first substrate 111 and the transparent second substrate 112. Through this, it is possible to prevent yellowing phenomenon from occurring when ultraviolet rays react with the optical pattern 160.

In particular, the third anti-ultraviolet layer 153 can block ultraviolet rays from entering into the edges of the display area DA where external ultraviolet rays can first reach, so that yellowing phenomenon at the edges of the display area DA can be minimized, thereby improving the clarity, visibility, and readability of the transparent display device 100.

The anti-ultraviolet member 150 can be disposed to surround the rear surface, top surface, and at least three side surfaces of the transparent display panel 110 between the transparent display panel 110 and the cover member 170 to prevent external foreign substances, such as moisture or oxygen, from penetrating into the transparent display panel 110, thereby improving the reliability of the transparent display panel 110. Furthermore, the anti-ultraviolet member 150 can absorb an impact applied to the transparent display panel 110 or buffer an external impact to protect the transparent display panel 110 and can completely block ultraviolet rays from entering into the transparent display panel 110.

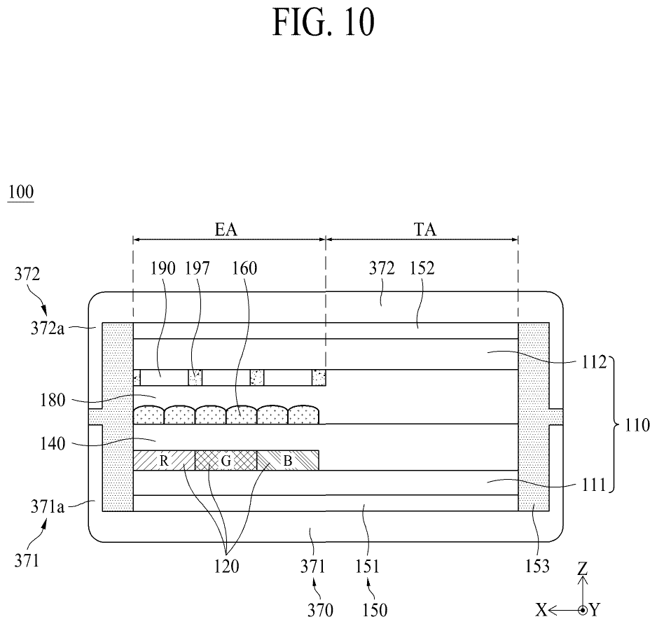

FIG. 10 is cross-sectional view of another embodiment of the transparent display device shown in FIG. 1.

Referring FIG. 10, the cover member 370 of the transparent display device 100 according to another embodiment of the present disclosure is disposed on the front surface and rear surface of the transparent display panel 110 to accommodate the transparent display panel therein. The cover member 370 includes a first cover 371 that accommodates the transparent display panel 110 and a second cover 372 through which an image is visible. The first cover 371 and the second cover 372 are disposed to face each other with the transparent display panel 110 between them.

The first cover 371 includes a first curved portion 371a that covers at least a portion of a side surface of the transparent display panel 110 in a shape that accommodates the transparent display panel 110. The first curved portion 371a is a portion of the first cover 371 covering an edge portion of the first substrate 111 of the transparent display panel 110 that is bent in a direction toward the second substrate 112 (or Z direction) to extend in the direction toward the second substrate 112 (or Z direction).

The second cover 372 is disposed on the second substrate 112 of the transparent display panel 110 to be coupled the first cover 371. The second cover 372 includes a second curved portion 372a with curved edge. One end of the second curved portion 372a is disposed to face one end of the first curved portion 371a so that the second curved portion 372a is coupled to the first curved portion 371a.

A third anti-ultraviolet layer 153 can be disposed between one end of the second bend 372a of the second cover 372 and one end of the first bend 371a of the first cover 371. The second curved portion 372a of the second cover 372 and the first curved portion 371a of the first cover 371 can be coupled via the third anti-ultraviolet layer 153.

The cover member 370 covers the top surface, the rear surface, and the side surface of the transparent display panel 110 and is coupled to the transparent display panel 110 via the anti-ultraviolet member 150 to protect the top surface, the rear surface, and the side surface of the transparent display panel 110 from external impacts, etc.

The first cover 371 and the second cover 372 can include a transparent glass or transparent plastic material. The first cover 371 and the second cover 372 can be a film-type including an organic material having impact-resistance and light-transmissive, for example, polymethylmethacrylate PMMA, polycarbonate PC, cycloolefin polymer COP, polyethylene terephthalate PET, polyimide PI, or polyaramid PA, and can include an inorganic material such as thin glass, sapphire, etc.

The cover member 370 is coupled to the transparent display panel 110 via the anti-ultraviolet member 150 disposed between the cover member 370 and the transparent display panel 110.

A predetermined internal space can be defined between inner portions of the first and second curved portions 371a and 372a and the side surface of the transparent display device 110. The third anti-ultraviolet layer 153 of the anti-ultraviolet member 150 can be disposed in the predetermined internal space between the first curved portion 371a and the side surface of the transparent display panel 110. Further, the third anti-ultraviolet layer 153 of the anti-ultraviolet member 150 can be disposed in the predetermined internal space between the second curved portion 372a and the side surface of the transparent display panel 110.

The third anti-ultraviolet layer 153 can be disposed to surround the optical pattern 160 inside the transparent display panel 110 on the side surface of the transparent display panel 110. The third anti-ultraviolet member 150 can absorb or reflect ultraviolet rays, thereby preventing external ultraviolet rays from entering into the transparent display panel 110 through the transparent first and second substrates 111 and 112 even if external ultraviolet rays is transmitted through the transparent cover member 370. Through this, it is possible to prevent yellowing phenomenon from occurring when ultraviolet rays react with the optical pattern 160.

In general, a transparent display device is transparent, unlike a general display device, so external light can pass through the inside of the transparent display device. At this time, organic material inside the transparent display device reacts with ultraviolet rays, which can cause yellowing phenomenon. However, in the transparent display device 100 according to the present disclosure, the third anti-ultraviolet layer 153 is disposed to surround at least three side surfaces of the transparent display panel 110 and the third anti-ultraviolet layer 153 can block ultraviolet rays from entering into the edges of the display area DA where external ultraviolet rays can first reach, so that yellowing phenomenon at the edges of the display area DA can be minimized.

Since the anti-ultraviolet member 150, including the third anti-ultraviolet layer 153, can be disposed to surround not only the top and rear surfaces of the transparent display panel 110 but also the edges of the transparent display panel 110, external ultraviolet rays can be prevented from entering into the transparent display panel 110, thereby minimizing yellowing phenomenon. Thus, it is possible to improve the clarity, visibility, and readability of the transparent display device 100.

The anti-ultraviolet member 150 can be disposed to surround the rear surface, top surface, and at least three side surfaces of the transparent display panel 110 between the transparent display panel 110 and the cover member 370 to prevent external foreign substances, such as moisture or oxygen, from penetrating into the transparent display panel 110, thereby improving the reliability of the transparent display panel 110. Furthermore, the anti-ultraviolet member 150 can absorb an impact applied to the transparent display panel 110 or buffer an external impact to protect the transparent display panel 110 and can completely block ultraviolet rays from entering into the transparent display panel 110.

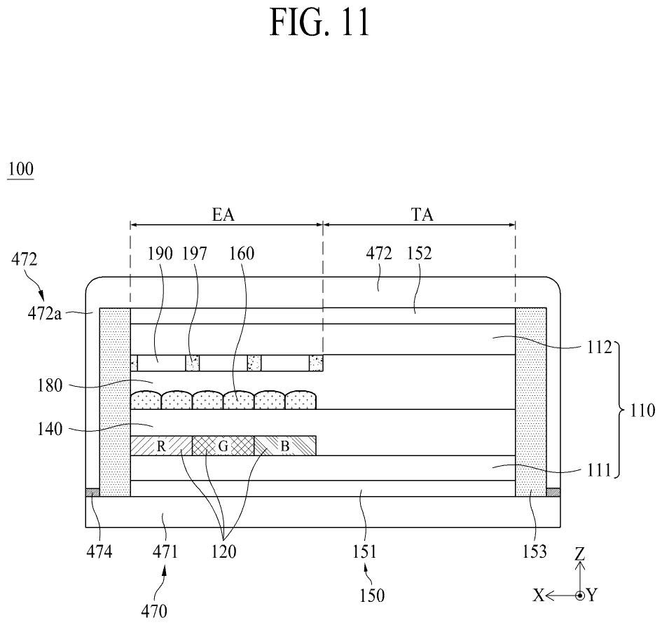

FIG. 11 is cross-sectional view of another embodiment of the transparent display device shown in FIG. 1.

Referring FIG. 11, the cover member 470 of the transparent display device 100 according to another embodiment of the present disclosure is disposed on the front surface and rear surface of the transparent display panel 110, and accommodates the transparent display panel 110 therein. The cover member 470 a first cover 471 disposed on the rear surface of the transparent display panel 110, a second cover 472 through which an image is visible, and an adhesive layer 474 that attaches the first cover 471 to the second cover 472. The first cover 471 and the second cover 472 are disposed to face each other with the transparent display panel 110 between them.

The first cover 471 supports the transparent display panel 110 and is disposed on the rear surface side of the first substrate 111 of the transparent display panel 110 with a larger area than the transparent display panel 110.

A first anti-ultraviolet layer 151 can be disposed between the top surface of the first cover 471 and the first substrate 111 of the transparent display panel 110. The first cover 471 can be coupled to the transparent display panel 110 via the first anti-ultraviolet layer 151.

A second anti-ultraviolet layer 152 can be disposed between the rear surface of the second cover 472 and the second substrate 112 of the transparent display panel 110. The second cover 472 can be coupled to the transparent display panel 110 through the second anti-ultraviolet layer 152.

The second cover 472 is shaped to cover the transparent display panel 110 and includes a curved portion 472a that covers the side surfaces of the first substrate 111 and the second substrate 112.

The curved portion 472a of the second cover 472 is a portion of the second cover 472 covering an edge portion of the second substrate 112 of the transparent display panel 110 that is bent in a direction toward the first substrate 111 (or Z direction) to extend in the direction toward the first substrate 111 (or Z direction).

One end of the curved portion 472a of the second cover 472 is disposed to extend to at least near the top surface of the first cover 471 so as to cover a side surface of the first substrate 111. The curved portion 472a of the second cover 472 can surround a side surface of the transparent display panel 110 such that at least a portion of the curved portion 472a is disposed parallel to the side surface of the transparent display panel 110.

The second cover 472 is coupled to the first cover 471 via the adhesive layer 474.

The adhesive layer 474 can be disposed between an edge of the top surface of the first cover 471 and one end of the curved portion 472a of the second cover 472 to attach the first cover 471 and the second cover 472 to each other, and prevent moisture penetration from the outside, and the like.

The adhesive layer 474 can be in the form of a double-sided tape, and an adhesive material can be provided on the top surface and the rear surface of the adhesive layer 474. The adhesive layer 474 can be disposed on the outside of the third anti-ultraviolet layer 153. Specifically, the third anti-ultraviolet layer 153 can be disposed between a side surface of the adhesive layer 474 and the transparent display panel 110 or between the side surface of the adhesive layer 474 and the first anti-ultraviolet layer 151.

A predetermined internal space can be defined between the inner side of the curved portion 472a of the second cover 472 and the side surface of the transparent display panel 110. A third anti-ultraviolet member 153 can be disposed in the predetermined internal space between the curved portion 472a of the second cover 472 and the side surface of the transparent display panel 110.

The third anti-ultraviolet layer 153 can be disposed to surround at least three side surfaces of the transparent display panel 110.

The third anti-ultraviolet layer 153 can be further disposed on an area excluding only the connection portion for connecting the driving parts to the transparent display panel 110 on one side surface of the transparent display panel 110.

The third anti-ultraviolet layer 153 is disposed on the side surface of the transparent display panel 110 and is disposed to cover at least one of the optical pattern 160, the optical insulating layer 180, and the color filter 190 inside the transparent display panel 110. The third anti-ultraviolet layer 153 can absorb or reflect ultraviolet rays to prevent external ultraviolet rays from entering into the transparent through the transparent first and second substrates 111 and 112.

Specifically, the third anti-ultraviolet layer 153 can absorb or reflect external ultraviolet rays that can enter into the transparent display panel 110 from the side surface of the transparent display panel 110. Through this, it is possible to prevent yellowing phenomenon from occurring when external ultraviolet rays reacts with the optical pattern 160 inside the transparent display panel 110.

The third anti-ultraviolet layer 153 can include a transparent organic material. The third anti-ultraviolet layer 153 can include a transparent resin material including an ultraviolet-blocking material. The third anti-ultraviolet layer 153 can include an ultraviolet absorber in the transparent resin layer.

The third anti-ultraviolet layer 153 can further include an adhesive material, the ultraviolet absorber, or the ultraviolet blocker in a transparent resin layer, thereby allowing the transparent display panel 110 and the cover member 170 to be more stably coupled.

The third anti-ultraviolet layer 153 can block ultraviolet rays from entering into the transparent display panel 110 by absorbing or reflecting at least the portion of light having a wavelength corresponding to the visible light range or less, thereby protecting the transparent display panel 110.

Specifically, the third anti-ultraviolet layer 153 can block light from entering into the transparent display panel 110 by absorbing or reflecting at least the portion of light having a wavelength of 350 nm or less.

The first anti-ultraviolet layer 151, the second anti-ultraviolet layer 152, and the third anti-ultraviolet layer 153 can be made of the same material.

In general, a transparent display device is transparent, unlike a general display device, so that external light can pass through the inside of the transparent display device. The transparent display panel 110 according to the present disclosure includes the optical patterns 160 including organic matter therein, and the third anti-ultraviolet layer 153 of the anti-ultraviolet member 150 is disposed to surround the optical patterns 160 inside the transparent display panel 110 from outside to absorb or reflect external ultraviolet rays, so that an interaction of the external ultraviolet rays and the optical patterns 160 in the display area DA can be blocked and yellowing phenomenon caused by oxidation reactions in the display area DA of the transparent display panel 110 can be prevented from occurring.

In particular, the third anti-ultraviolet layer 153 can block ultraviolet rays from entering into the edges of the display area DA where external ultraviolet rays can first reach, so that yellowing phenomenon at the edges of the display area DA can be minimized.

The anti-ultraviolet member 150, including the third anti-ultraviolet layer 153, can be disposed to surround not only the top and rear surfaces of the transparent display panel 110 but also the edges of the transparent display panel 110. Accordingly, when a user uses the transparent display device 100 in an external environment, external ultraviolet rays can be prevented from entering into the transparent display panel 110, thereby minimizing yellowing phenomenon, thereby improving the clarity, visibility, and readability of the transparent display device 100.

The transparent display device 100 according to the present disclosure can increase the lifespan of the transparent display device by securing rigidity and reliability and improving quality, so that the manufacturing process for producing the transparent display device 100 can be reduced and the generation of greenhouse gases due to the manufacturing process can be reduced, thereby implementing ESG (Environment/Social/Governance).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

[DESCRIPTION OF THE LABELS]

| | |
|---|---|
| 100: transparent display device | 110: transparent display panel |
| 111: first substrate | 112: second substrate |
| 124: light emitting device layer | 125: bank |
| 150: encapsulation layer | 160: optical patterns |
| 170, 270, 370, 470: cover member | |
| 180: optical insulating layer | 190: color filter |
| 197: black matrix | 474: adhesive layer |

1. A transparent display device, comprising:
a transparent display panel including a display area and a non-display area disposed outside of the display area, and including a first substrate and a second substrate;
wherein the first substrate and the second substrate bonded together, the first substrate and the second substrate include the display area, and the display area includes a transmissive area and an emission area;
an anti-ultraviolet member including:
a first anti-ultraviolet layer disposed on a lower portion of the transparent display panel;
a second anti-ultraviolet layer disposed on an upper portion of the transparent display panel; and
a third anti-ultraviolet layer disposed on a side portion of the transparent display panel; and
a cover member disposed outside the anti-ultraviolet member and including a first cover covering the lower portion of the transparent display panel and a second cover covering the upper portion of the transparent display panel.

2. The transparent display device of claim 1, further comprising a plurality of optical patterns in a lens shape disposed in the emission area.

3. The transparent display device of claim 2, wherein the third anti-ultraviolet layer is disposed on an edge of the transparent display panel and configured to surround the plurality of optical patterns on at least three sides.

4. The transparent display device of claim 1, wherein the first anti-ultraviolet layer is disposed between the first substrate and the first cover, and
wherein the second anti-ultraviolet layer is disposed between the second substrate and the second cover.

5. The transparent display device of claim 1, wherein the third anti-ultraviolet layer is disposed on a side surface of the first substrate and a side surface of the second substrate.

6. The transparent display device of claim 1, wherein the third anti-ultraviolet layer is disposed to surround at least three side surfaces of the transparent display panel.

7. The transparent display device of claim 1, wherein the third anti-ultraviolet layer comprises a transparent resin layer including an ultraviolet blocker or an ultraviolet absorber.

8. The transparent display device of claim 7, wherein the first anti-ultraviolet layer, the second anti-ultraviolet layer, and the third anti-ultraviolet layer are made of a same material.

9. The transparent display device of claim 1, wherein the third anti-ultraviolet layer absorbs or reflects at least a portion of light having a wavelength of approximately 350 nm or less.

10. The transparent display device of claim 1, wherein the cover member comprises a curved portion configured to cover side surfaces of the transparent display panel.

11. The transparent display device of claim 10, wherein the third anti-ultraviolet layer is disposed between the curved portion and the side surfaces of the transparent display panel.

12. The transparent display device of claim 10, wherein the curved portion is disposed on at least one of an edge of the first cover and an edge of the second cover.

13. The transparent display device of claim 10, wherein the curved portion is disposed on an edge of the first cover and an edge of the second cover, and
wherein the curved portion of the first cover and the curved portion of the second cover are coupled through the third anti-ultraviolet layer.

14. The transparent display device of claim 10, wherein the cover member further comprises an adhesive layer disposed between the first cover and the second cover,
wherein the curved portion is disposed an edge of the second cover, and
wherein the curved portion of the second cover is coupled to the first cover through the adhesive layer.

15. The transparent display device of claim 14, wherein the adhesive layer is disposed on an outside of the third anti-ultraviolet layer, and
wherein the third anti-ultraviolet layer is disposed between the adhesive layer and the transparent display device.

16. The transparent display device of claim 1, wherein the third anti-ultraviolet layer is disposed to surround an edge of the transparent display panel.

17. The transparent display device of claim 2, further comprising:
a light emitting device layer in which a first electrode, a light emitting layer, and a second electrode are stacked in the emission area; and
an encapsulation layer disposed on the light emitting device layer,
wherein the plurality of optical patterns are disposed on the encapsulation layer.
